(19) United States
(12) Patent Application Publication
(10) Pub. No.: US 2013/0283609 A1
(43) Pub. Date: Oct. 31, 2013

(54) METHOD FOR MANUFACTURING SUPPORTING BOARDS OF LIGHT EMITTING DIODE MODULES

(71) Applicant: ADVANCED OPTOELECTRONIC TECHNOLOGY INC., (US)

(72) Inventors: Hou-Te LIN, Hsinchu (TW); Shih-Yuan HSU, Hsinchu (TW)

(73) Assignee: ADVANCED OPTOELECTRONIC TECHNOLOGY, INC., Hsinchu Hsien (TW)

(21) Appl. No.: 13/851,938

(22) Filed: Mar. 27, 2013

(30) Foreign Application Priority Data
Apr. 28, 2012 (CN) 201210129493.X

(51) Int. Cl. H05K 3/20; H05K 3/00

(52) U.S. Cl. CPC H05K 3/20; H05K 3/0044
USPC 29/845

(57) ABSTRACT

A method for manufacturing supporting boards of light emitting diode modules comprises the following steps: providing a substrate which defines a plurality of through holes and receiving holes therein; providing an engaging plate which includes a plurality of electrode structures and brackets connecting the electrode structures with a connecting frame, each of the electrode structures forming a receiving cavity and an inserting part; providing a shaping roller assembly whereon the substrate and the engaging plate are wound, stacking the substrate and the engaging plate together, rotating the shaping roller assembly to make the shaping roller assembly press the stacked substrate and engaging plate, such that the through holes of the substrate are received in the receiving cavities of the engaging plate and the inserting parts of the electrode structures are inserted into the receiving holes of the substrate, whereby the supporting boards are formed.

### BACKGROUND

1. Technical Field

The disclosure generally relates to a method for manufacturing supporting boards of light emitting diode (LED) modules, particularly, by roller pressing a polymer substrate and a metallic engaging plate together.

2. Description of Related Art

A conventional method for manufacturing supporting boards of an LED module comprises following steps: providing a mold with a plurality of molding cavities, and injecting a desired molding material into the molding cavities to obtain substrates each corresponding to a molding cavity. Metallic electrodes are then brought to be inserted into the substrates one by one, whereby a substrate and corresponding electrodes therein form a corresponding supporting board. The above-mentioned process is complicated and time-consuming, especially in manufacturing the supporting boards in a large quantity.

What is needed, therefore, is a method for manufacturing supporting boards of LED modules which can overcome the above described shortcomings.

### BRIEF DESCRIPTION OF THE DRAWINGS

FIG. 1 is a flowchart of a method for manufacturing supporting boards of LED modules in accordance with an exemplary embodiment of the present disclosure.

FIGS. 2-9 are schematic views showing steps of the method for manufacturing supporting boards of LED modules of the present disclosure.

### DETAILED DESCRIPTION

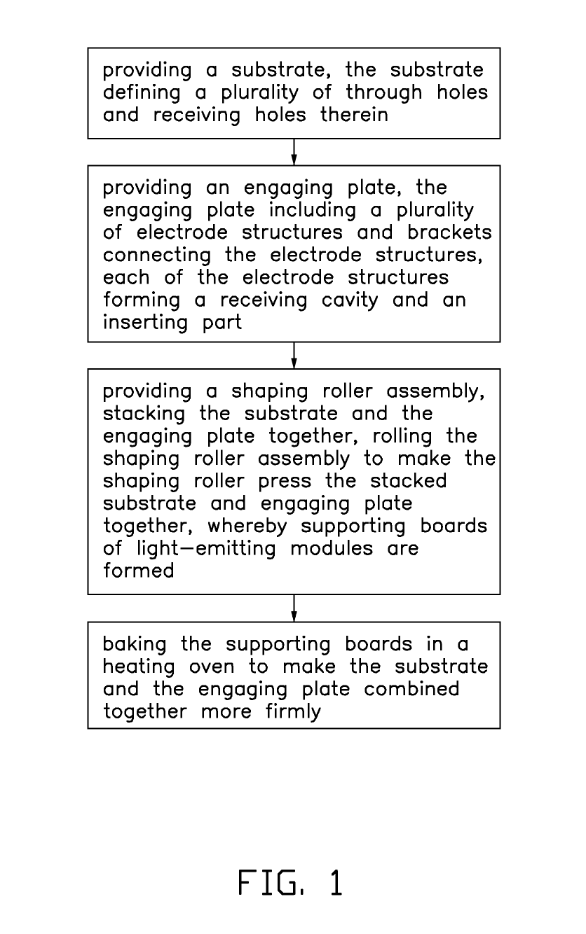

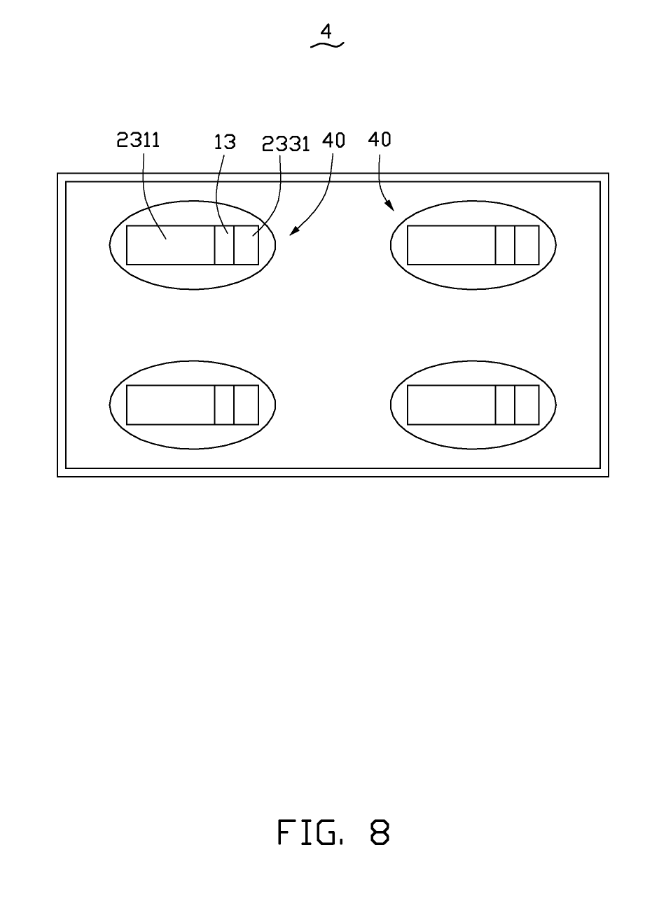

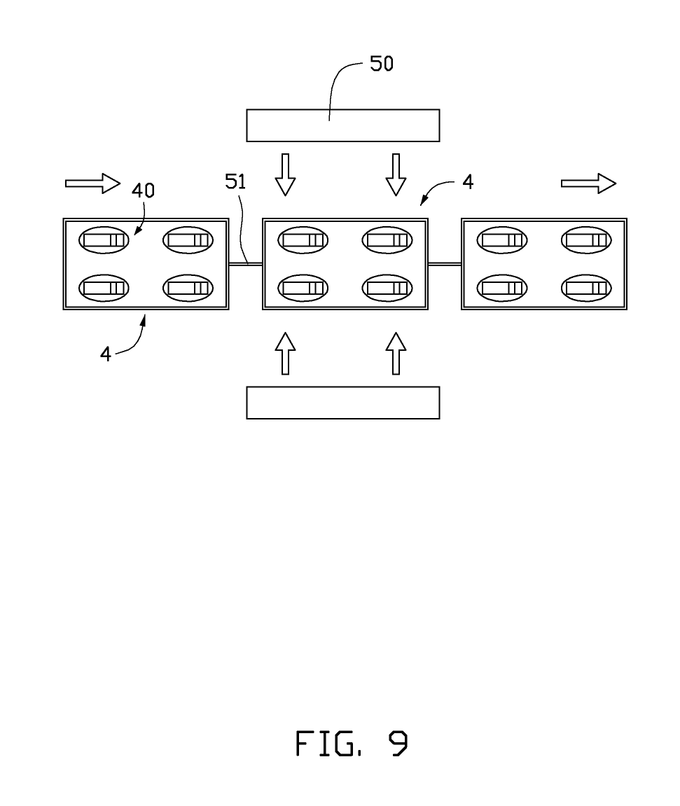

Referring to FIG. 1, a method for manufacturing supporting boards of an LED modules (shown in FIGS. 8-9) in accordance with an exemplary embodiment of the present disclosure comprises the following steps.

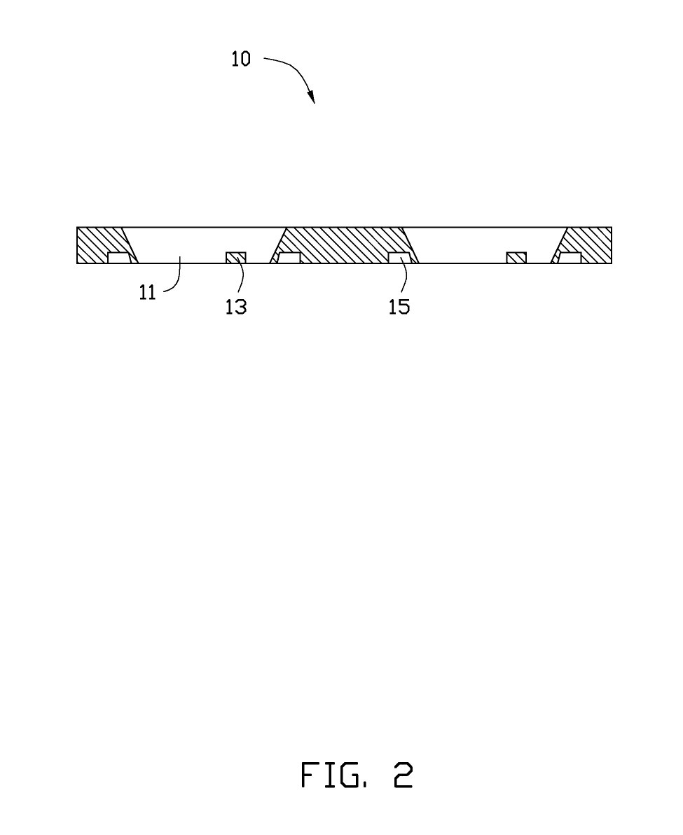

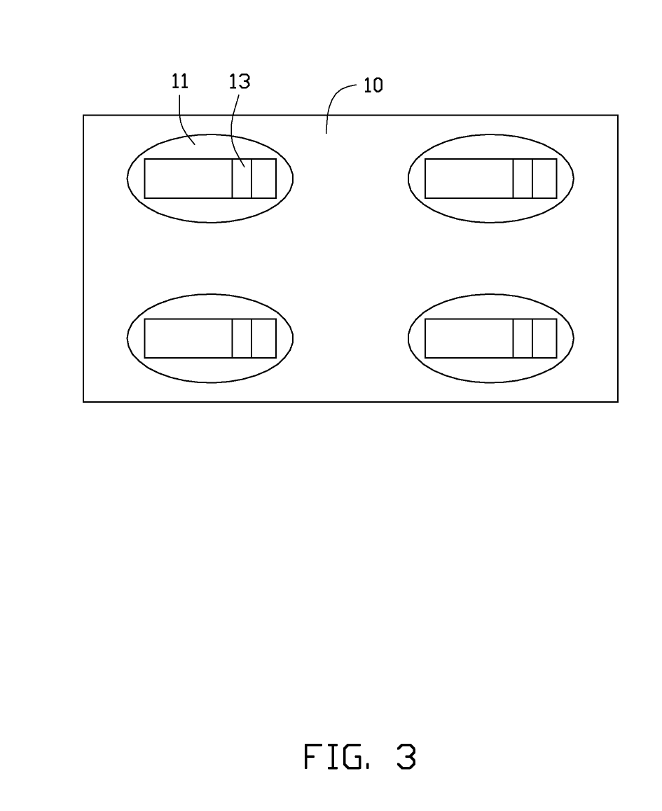

Referring also to FIGS. 2-3, the first step is providing a substrate 10. The substrate 10 is a flat and flexible plate with a uniform thickness. The substrate 10 is made of silicone resin, silicone, epoxy or polymeric materials. A plurality of through holes 11 and receiving holes 15 are defined in the substrate 10. The through holes 11 are used to receive light emitting diodes (not shown) therein. The through holes 11 are spaced from each other and arranged in two rows along a longitudinal direction of the substrate 10. In this embodiment, the number of the through holes 11 is four.

Each through hole 11 is recessed from a top surface of the substrate 10 to a bottom surface of the substrate 10. A cross-section of a top end of each through hole 11 is circular, and a cross-section of a bottom end of each through hole 11 is rectangular. A bore size of each through hole 11 decreases from the top end to the bottom end.

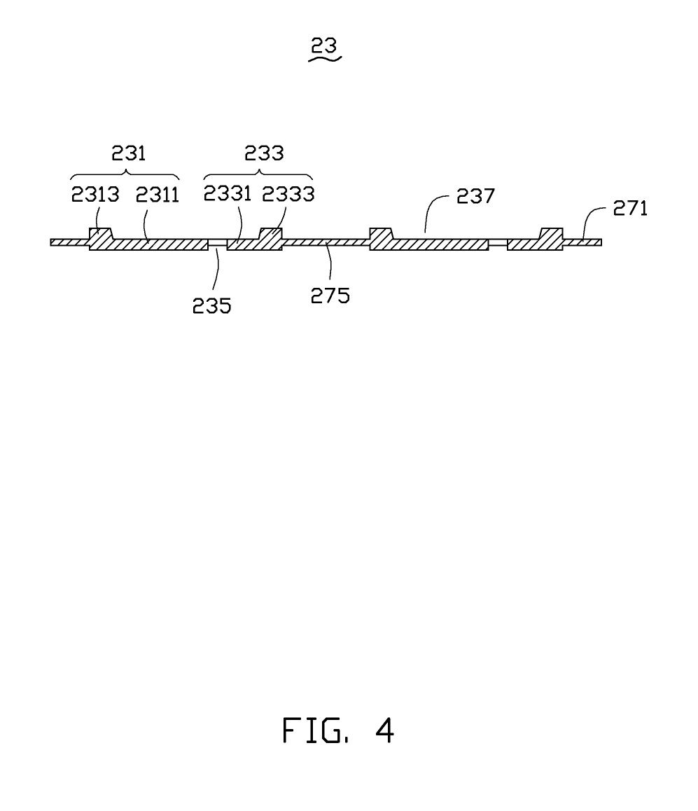

An isolating portion 13 is received in each through hole 11. The isolating portion 13 is located at the bottom end of the through hole 11, and opposite ends of the isolating portion 13 connect with the substrate 10 defining a border of the bottom end of the through hole 11. The isolating portion 13 is used to form an insulating part to separate and electrically insulate a first electrode 231 of an electrode structure 23 (shown in FIG. 4) from a second electrode 233.

Each receiving hole 15 is recessed from the bottom surface to a central portion of the substrate 10. These receiving holes 15 are spaced from each other and used to receive an inserting part 2313 of a first electrode 231 and an inserting part 2333 of a second electrode 233 (shown in FIG. 4) respectively.

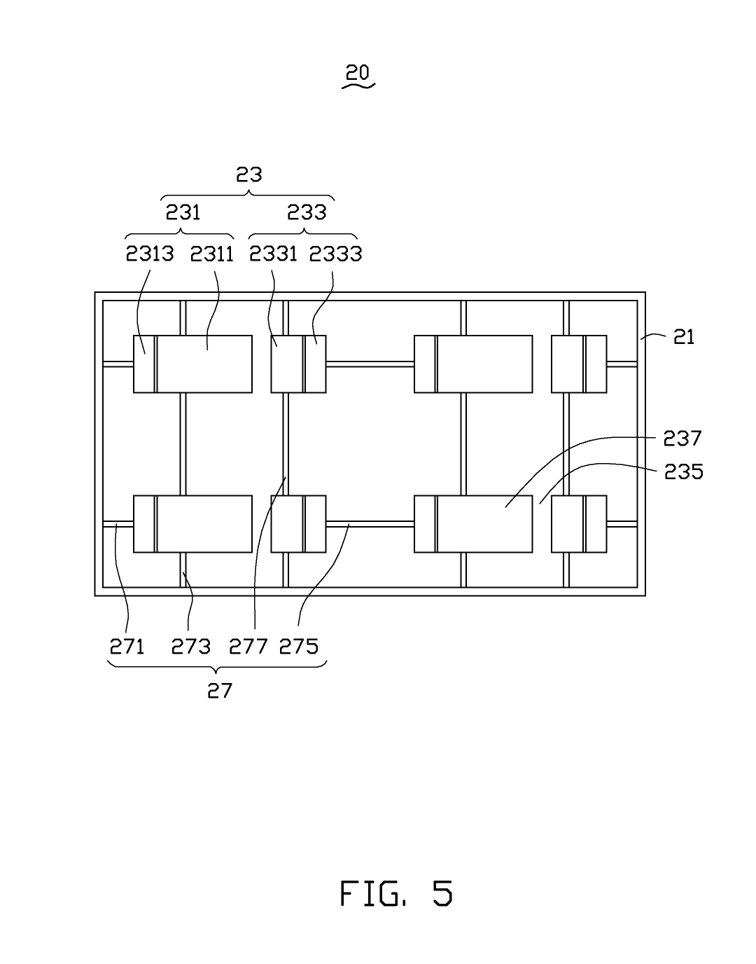

Referring to FIGS. 4-5, the second step is providing an engaging plate 20. The engaging plate 20 comprises a hollow connecting frame 21, a plurality of electrode structures 23 enclosed by the connecting frame 21 and a plurality of brackets 27 connecting the electrode structures 23 to the connecting frame 21.

The connecting frame 21 is a metallic and rectangular frame. The connecting frame 21 is a frame with a uniform thickness, which is made of a flexible metallic material. Preferably, the engaging plate 20 is made of a sheet copper.

Each electrode structure 23 comprises a first electrode 231 and a second electrode 233. The first electrode 231 and the second electrode 233 are spaced from each other. The electrode structures 23 and the connecting frame 21 are spaced from each other. These electrode structures 23 are arrayed in two rows along a longitudinal direction of the substrate 10. In this embodiment, the number of the electrode structures 23 is four.

Each first electrode 231 comprises a first main part 2311 and a first inserting part 2313. The first main part 2311 is a flat metal plate. The first inserting part 2313 is protruding from a top surface of an outer end of the first main part 2311. A front side view of each first inserting part 2313 is trapeziform (shown in FIG. 4). Each first inserting part 2313 tapers from a bottom end connecting the first main part 2311 to a top end away from the first main part 2311.

Each second electrode 233 comprises a second main part 2331 and a second inserting part 2333. The second main part 2331 is a flat metal plate. The second inserting part 2333 is protruding from a top surface of an outer end of the second main part 2331. A front side view of each second inserting part 2333 is trapeziform (shown in FIG. 4). Each second inserting part 2333 tapers from a bottom end connecting the second main part 2331 to a top end away from the second main part 2331.

A receiving slot 235 is defined between an inner end of the first main part 2311 and an inner end of the second main part 2331. The slot 235 extends along the inner end of the first main part 2311 and the inner end of the second main part 2331. The slot 235 is used to receive an isolating part 13 therein.

A receiving cavity 237 is defined between the first inserting part 2313 and the second inserting part 2333. A front side view of the cavity 237 is trapeziform. A width of the cavity 237 tapers from a top end of the first inserting part 2313 and the second inserting part 2333 to the bottom end of the first inserting part 2313 and the second inserting part 2333. Each cavity 237 is used to receive a lower portion of a corresponding through hole 11 of the substrate 10 therein and communicate with an upper portion of the corresponding through hole 11.

The brackets 27 comprise metallic bars 271, 273, 275 and 277. The electrode structures 23 are connected with each other by the bars 271, 273, 275 and 277 of the brackets 27, respectively.

The bars 271 and 273 connect side surfaces of an outer end of the first electrode 231 and the second electrode 233 to a corresponding inner surface of the connecting frame 21, respectively. The bar 275 connects two adjacent electrode structures 23 along a longitudinal direction of the connecting frame 21. The bar 277 connects two adjacent first electrodes 231 along a transverse direction of the connecting frame 21. The bar 277 also connects two adjacent second electrodes 233 along a transverse direction of the connecting frame 21.

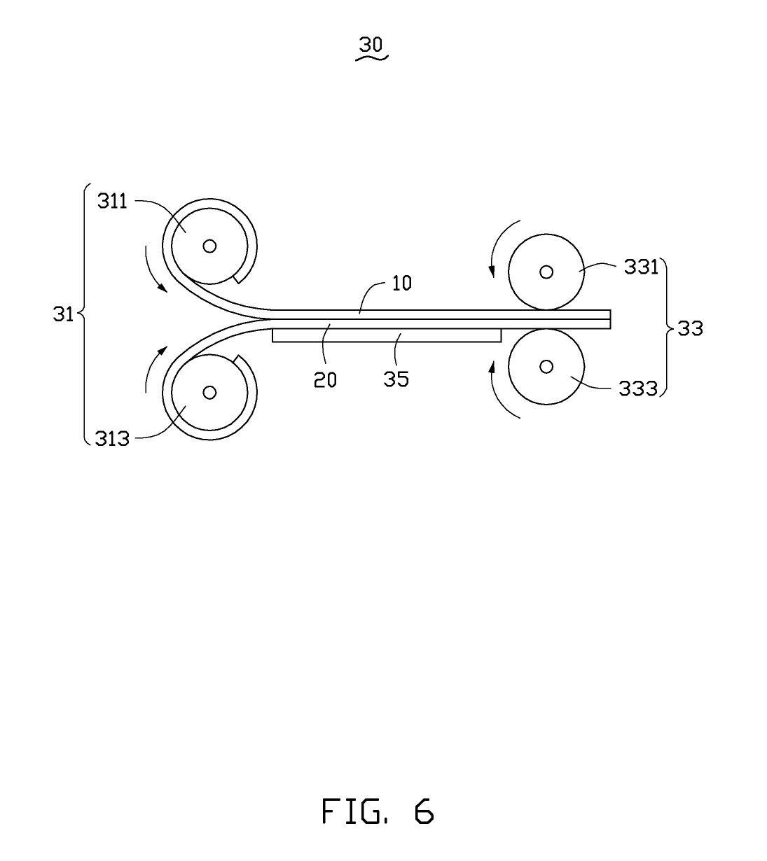

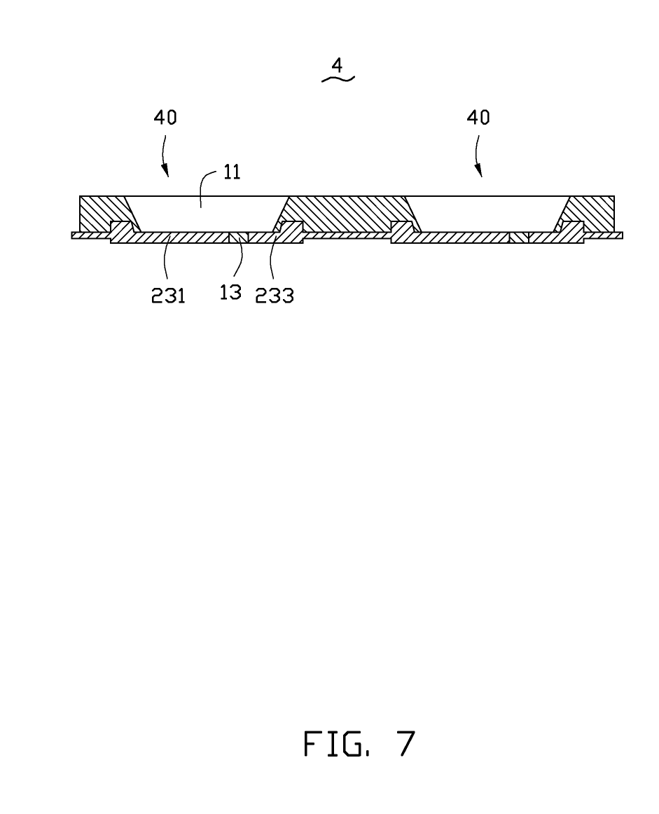

Referring to FIGS. 6-8, the third step is providing a shaping roller assembly 30, stacking the substrate 10 and the engaging plate 20 together, and rotating the shaping roller assembly 30 to make the shaping roller assembly 30 press the stacked substrate 10 and engaging plate 20, such that the lower portions of the through holes 11 of the substrate 10 are received in the cavity 237 of the engaging plate 20, and the inserting parts (2313, 2333) of the electrode structures 23 are inserted into the receiving holes 15 of the substrate 10, whereby four interconnected supporting boards 40 for four LED modules are formed. The four interconnected supporting boards 40 form a unit 4.

The shaping roller assembly 30 comprises a first roller group 31, a second roller group 33 and a transmitting device 35 supporting the substrate 10 and the engaging plate 20. The transmitting device 35 may be a conveyor belt.

The first roller group 31 is spaced from the second roller group 33 along a longitudinall direction of the transmitting device 35. The first roller group 31 comprises a first roller 311 and a second roller 313. The first roller 311 is located over and spaced from the second roller 313 with a large distance. The first roller 311 is rotated to transfer the substrate 10 toward the second roller group 33 via the transmitting device 35 and second roller 313 is rotated to transfer the engaging plate 20 toward the second roller group 33 via the transmitting device 35.

The second roller group 33 comprises a third roller 331 and a fourth roller 333. The third roller 331 is located over and spaced from the fourth roller 333 with a small distance which is substantially the same as a thickness of each of the supporting boards 40. The third roller 331 is rotated to cooperate with the fourth roller 333 to roll to press the substrate 10 and the engaging plate 20 together to obtain the supporting boards 40.

Before rotating the shaping roller assembly 30, the substrate 10 is twined around the first roller 311, and the engaging plate 20 is twined around the second roller 313; then the shaping roller assembly 30 is activated to make the substrate 10 leave the first roller 311 and the engaging plate 20 leave the second roller 313 whereby the substrate 10 and the engaging plate 20 are transferred toward on the transmitting device 35. At an end of the transmitting device 35 neighboring the first roller group 31, the substrate 10 and the engaging plate 20 begin to be stacked together. Over the transmitting device 35, each through hole 11 of the substrate 10 is corresponding with a cavity 237 of the engaging plate 20; each two adjacent receiving holes 15 of the substrate 10 are corresponding with the first inserting part 2313 and the second inserting part 2333 of the engaging plate 20, respectively; each isolating part 13 is corresponding with a receiving slot 235 of the engaging plate 20. Then, the stacked substrate 10 and engaging plate 20 are transmitted to the second roller group 33 by the transmitting device 35. The third roller 331 and the fourth roller 333 press the substrate 10 and the engaging plate 20 toward each other to make the lower portions of the through holes 11 of the substrate 10 received in the corresponding cavity 237 of the engaging plate 20, the first inserting part 2313 and the second inserting part 2333 inserted into the corresponding receiving holes 15 of the substrate 10, and the isolating part 13 of the substrate 10 received in the receiving slot 235 of the engaging plate 20. Thus, the four interconnected supporting boards 40 for four LED modules are formed by compressing the substrate 10 and the engaging plate 20 together.

Referring to FIG. 9, the fourth step is to provide a heating oven 50 to bake the supporting boards 40 to make the substrate 10 and the engaging plate 20 combined together more firmly. The supporting boards 40 are transmitted into the heating oven 50, and baked in the heating oven 50 at a high temperature. In this embodiment, a unit 4 comprising four interconnected supporting boards 40 is connected end to end with a neighboring unit 4 by a metal bar 51; such an arrangement makes the baking of the supporting boards 40 more efficiently since a quite large number of the supporting boards 40 can be continuously transmitted through the heating oven 50 to be baked. The units 4 can be separated from each other by severing the metal bars 51 after the backing thereof is complete. After mounting of four LED chips (not shown) to the four interconnected supporting boards 40, the four interconnected supporting boards 40 can be separated from each other by a severing operation to the unit 4 to form four LED modules (not shown).

Compared with the conventional method of manufacturing the supporting boards for LED modules, the benefits of the method of roller pressing the substrate 10 and the engaging plate 20 in accordance with the present disclosure are simple and time-saving, especially in manufacturing the supporting boards 40 with a very large quantity.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A method for manufacturing supporting boards of light emitting diode modules comprising following steps:
providing a non-metallic substrate, the substrate defining a plurality of through holes and receiving holes therein;
providing a metallic engaging plate, the engaging plate including a plurality of electrode structures and brackets connecting the electrode structures, each of the electrode structures forming a receiving cavity and an inserting part; and
providing a shaping roller assembling, mounting the substrate and the engaging plate on the shaping roller assembly, rotating the shaping roller assembly to stack the substrate and the engaging plate together, and then roller pressing the stacked substrate and engaging plate together, such that the through holes of the substrate are received in the receiving cavities of the engaging plate and the inserting parts of the electrode structures are inserted into the receiving holes of the substrate, whereby a plurality of interconnected supporting boards of light-emitting modules is formed, each supporting board comprising a corresponding electrode structure.

2. The method of claim 1 further comprising a step of baking the interconnected supporting boards in an oven to make the substrate and the engaging plate combined together more firmly after the step of forming the interconnected supporting boards.

3. The method of claim 1, wherein the shaping roller assembly comprises a first roller group, the first roller group comprises a first roller and a second roller, the substrate twines around the first roller, the engaging plate twines around the second roller, when the shaping roller assembly is rotated, the first roller and the second roller send the substrate and the engaging plate to a predetermined position where the substrate and the engaging plate are stacked together.

4. The method of claim 3, wherein the shaping roller assembly further comprises a second roller group, and the second roller group comprises a third roller and a fourth roller which are used to press the stacked substrate and engaging plate into the supporting boards.

5. The method of claim 4, wherein the shaping roller assembly comprises a transmitting device, when the first roller group rotates, the substrate and the engaging plate are transferred to the transmitting device to be stacked together, and then, the stacked substrate and the engaging plate are transmitted by the transmitted device to the second roller group to be pressed.

6. The method of claim 1, wherein a cross-section of a top end of each of the through holes is circular, and a cross-section of a bottom end of each of the through holes is rectangular.

7. The method of claim 6, wherein a bore size of each of the through holes decreases from the top end to the bottom end thereof.

8. The method of claim 1, wherein the corresponding electrode structure comprises a first electrode and a second electrode, and a receiving slot is defined between the first electrode and the second electrode to space the first electrode from the second electrode.

9. The method of claim 8, wherein an isolating portion is formed in the substrate and the isolating portion is corresponding with the receiving slot.

10. The method of claim 9, wherein the isolating portion is located at a bottom end of each of the through holes, and opposite ends of the isolating portion connect the substrate defining a border of the bottom end of each of the through holes.

11. The method of claim 8, wherein the first electrode comprises a first main portion and a first inserting part protruding from an outer end of the first main portion, and the second electrode comprises a second main portion and a second inserting portion protruding from an outer end of the second main portion.

12. The method of claim 11, wherein a receiving cavity is defined between the first inserting portion and the second inserting portion, and the receiving cavity is used to receive the bottom end of each of the through holes therein.

13. The method of claim 1, wherein the engaging plate comprises a hollow connecting frame, the electrode structures are enclosed by the connecting frame, and the electrode structures are connected to the connecting frame by the brackets.

14. The method of claim 13, wherein the brackets comprise a plurality of connecting bars, and the electrode structures and the connecting frame are connected by the connecting bars.
